(19) United States
(12) Patent Application Publication
(10) Pub. No.: US 2003/0161418 A1
(43) Pub. Date: Aug. 28, 2003

(54) Blind narrow-band interference canceller using a prediction error method

(76) Inventors: Greg Steele, Fremont, CA (US); Eric Fain, Santa Clara, CA (US)

Correspondence Address: Keith D. Nelson, Lockheed Martin Corporation, Building 220, Mail Stop A08, P.O. Box 49041, San Jose, CA, 95161-9041, US

(21) Appl. No.: 10/080,861

(22) Filed: Feb. 22, 2002

(51) Int. Cl. H03D 1/04; H03K 5/01; H04B 1/10; H04L 1/00

(52) U.S. Cl. 375/346; 375/350

(57) ABSTRACT

Blind narrow-band interference cancellation apparatus and methods that implement an algorithm that adapts an antenna array or a finite impulse response equalizer, or a combination thereof, to cancel narrow-band interference in a communication signal. The apparatus and methods comprise an algorithm for removing an unknown narrow-band interferer from a communications signal of interest, so that the desired signal may be lock on to. In implementing the cancellation apparatus and methods, the received signal is oversampled either in time or in space. This oversampled signal contains a statistically white component (the signal of interest) and a correlated component (the narrow-band interferer). A prediction-error filter is formed using correlation statistics of the oversampled signal. Filtering the oversampled signal produces an output that is statistically white, containing most of the signal of interest, and a small portion of the interference. The output of the prediction-error filter contains a sufficient facsimile of the desired signal to allow an adaptive decision-feedback equalizer to lock on to the signal by making correct decisions on the output data stream.

### BACKGROUND

The present invention relates generally to interference cancellation in communication systems, and more particularly, to interference cancellers, methods and prediction error algorithms for providing blind narrow-band interference cancellation.

A paper by Brian G. Agee, et al. entitled “Spectral Self-Coherence Restoral: A New Approach to Blind Adaptive Signal Extraction Using Antenna Arrays”, discusses an “approach to blind adaptive signal extraction using narrowband antenna arrays”. The paper states that “This approach has the capability to extract communication signals from co-channel interference environments using only known spectral correlation properties of those signals—in other words, without using knowledge of the content or direction of arrival of the transmitted signals, or the array manifold or background noise covariance of the receiver, to train the antenna array.”

Another paper by Constantinos B. Papadias, et al. entitled “Fractionally spaced Equalization of Linear Polyphase Channels and Related blind Techniques based on Multichannel Linear Prediction” discusses “the problem of linear equalization of polyphase channels and its blind implementation.” It is stated in this paper that “These channels may result from oversampling the single output of a transmission channel or/and by receiving multiple outputs of an antenna array. A number of recent contributions in the field of blind channel identification have shown that polyphase channels can be blindly identified using only second-order statistics (SOS) of the output. In this work, we are mostly interested in the blind linear equalization of these channels: After some elaboration on the specifics of the equalization problem for polyphase channels, we show how optimal settings of various well-known types of linear equalization structures can be obtained blindly using only the output's SOS by using multichannel linear prediction or related techniques.”

It is an objective of the present invention to provide for improved interference cancellers, methods and prediction error algorithm for providing blind narrow-band interference cancellation.

### SUMMARY OF THE INVENTION

To accomplish the above and other objectives, the present invention provides for a blind narrow-band interference cancellers and prediction error methods that comprise an algorithm for adapting an antenna array or a finite impulse response (FIR) equalizer, or a combination thereof, to cancel narrow-band interference in a communication signal. The method is based upon the “whitening” property of a linear prediction error filter.

The blind narrow-band interference canceller and prediction error method comprises an algorithm for removing an unknown narrow-band interferer from a communications signal of interest, so that the receiver may lock on to the desired signal. The canceller and method is based on several principles.

Firstly, the received signal is oversampled either in time or in space. An antenna array with sufficient spacing will effectively oversample a signal, even if each antenna is critically sampled in time. This oversampled signal contains a statistically white component (the signal of interest) and a correlated component (the narrow-band interferer).

Secondly, a prediction-error filter can be computed from the correlation statistics of the oversampled signal. Filtering the signal with this filter produces an output that is statistically white, containing most of the signal of interest, and a small portion of the interference.

Finally, the output of the prediction-error filter contains a sufficient facsimile of the desired signal to allow an adaptive decision-feedback equalizer to lock on to the signal by making correct decisions on the output data stream. Without the initial filtering, the adaptive decision-feedback equalizer would not be able to acquire lock.

One exemplary implementation of the present invention provides for a blind narrow-band interference canceller that uses a prediction error algorithm and spatial oversampling. Another exemplary implementation of the present invention provides for a blind narrow-band interference canceller that uses a prediction error algorithm and temporal oversampling.

The present invention may be implemented in a simple manner for real-time operation. The present invention also has good convergence properties.

### BRIEF DESCRIPTION OF THE DRAWINGS

The various features and advantages of the present invention may be more readily understood with reference to the following detailed description taken in conjunction with the accompanying drawing, wherein like reference numerals designate like structural elements, and in which:

FIG. 1 shows a simplified diagram of a first exemplary communication receiver system comprising an exemplary blind narrow-band interference canceller and prediction-error algorithm in accordance with the principles of the present invention that uses spatial oversampling;

FIG. 2 shows a simplified diagram of a second exemplary communication receiver system comprising the blind narrow-band interference canceller and prediction-error algorithm in accordance with the principles of the present invention that uses temporal oversampling;

FIG. 3 illustrates input samples at the two antennas of the system shown in FIG. 1;

FIG. 4 illustrates the output of the prediction error filter of the system shown in FIG. 1;

FIG. 5 illustrates the equalized output of the canceller shown in FIG. 1; and

FIG. 6 is a flow chart that illustrates an exemplary interference cancellation method in accordance with the principles of the present invention.

### DETAILED DESCRIPTION

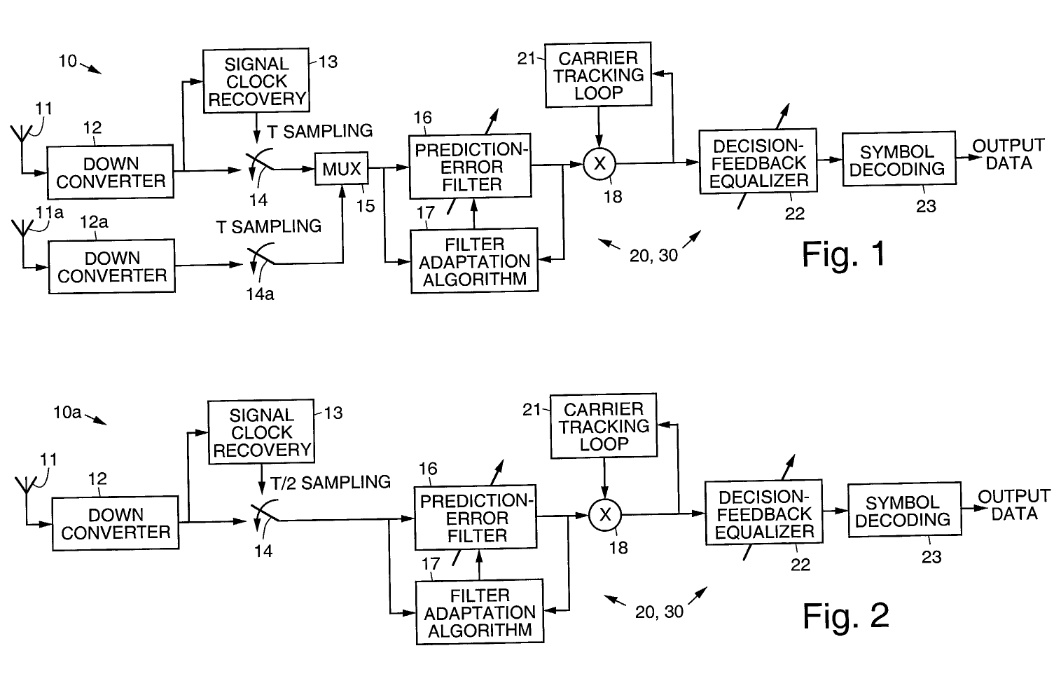

Referring to the drawing figures, FIG. 1 shows a simplified diagram of a first exemplary communication receiver system 10 comprising a blind narrow-band interference canceller 20 and prediction-error algorithm 30 in accordance with the principles of the present invention. In this system 10, multiple antennas 11 are used to provide spatial oversampling of received wideband data signals.

The first exemplary communication receiver system 10 comprises first and second receive antennas 11, 11a that are respectively coupled to first and second downconverters 12, 12a. The output of the first downconverter 12 is input to a signal clock recovery circuit 13 and to a first input of a first sampling circuit 14. The output of the signal clock recovery circuit 13 is input to a second input of the first sampling circuit 14 to cause sampling of the input data signals at a sampling rate T.

The output of the second downconverter 12a is input to a second sampling circuit 14a. The output of the signal clock recovery circuit 13 is also input to the second sampling circuit 14a to cause sampling at the sampling rate T. The respective outputs of the first and second sampling circuits 14, 14a are input to a multiplexer (MUX) 15, whose multiplexed output signal is input to the present blind narrow-band interference canceller 20.

The blind narrow-band interference canceller 20 implements a prediction-error algorithm 30 primarily using a prediction-error filter 16, a filter adaptation circuit 17, and an adaptive decision-feedback equalizer 22. In particular, the output of the multiplexer 15 is input to the prediction-error filter 16 and the filter adaptation circuit 17. The output of the prediction-error filter 16 is also input to the filter adaptation circuit 17 and to a first input of a multiplier 18. The output of the filter adaptation circuit 17 is input to the prediction-error filter 16 to adapt it.

The output of the multiplier 18 is fed back through a carrier tracking loop 21 to a second input of thee multiplier 18. The output of the multiplier 18 is input to the adaptive decision-feedback equalizer 22. The output of the adaptive decision-feedback equalizer 22 is processed by a symbol decoding or recovery circuit 23 which outputs the data signals received by the communication receiver system 10 without interference.

FIG. 2 shows a simplified diagram of a second exemplary communication receiver system 10a comprising the blind narrow-band interference canceller 20 and prediction-error method 30 in accordance with the principles of the present invention.

The second exemplary communication receiver system 10a is a single-antenna system 10a employing temporal oversampling. The second exemplary communication receiver system 10a is substantially the same as the first embodiment but has only a single receive channel.

The second exemplary communication receiver system 10 comprises a receive antenna 11 that is coupled to a downconverter 12. The output of the downconverter 12 is input to a signal clock recovery circuit 13 and to a first input of a sampling circuit 14. The output of the signal clock recovery circuit 13 is input to a second input of the sampling circuit 14 to cause sampling of the input data signals at a sampling rate T/2. The output of the sampling circuit 14 is input to the present blind narrow-band interference canceller 20.

The output of the sampling circuit 14 is input to a prediction-error filter 16 and to a filter adaptation circuit 17. The output of the prediction-error filter 16 is also input to the filter adaptation circuit 17 and to a first input of a multiplier 18. The output of the filter adaptation circuit 17 is input to the prediction-error filter 16 to adapt it.

The output of the multiplier 18 is fed back through a carrier tracking loop 21 to a second input of thee multiplier 18. The output of the multiplier 18 is input to the adaptive decision-feedback equalizer 22. The output of the adaptive decision-feedback equalizer 22 is processed by a symbol decoding or recovery circuit 23 which outputs the data signals received by the communication receiver system 10 without interference.

The blind narrow-band interference canceller 20 and prediction error algorithm 30 used in the systems 10, 10a shown in FIGS. 1 and 2 remove an unknown narrowband interfering signal from a communications signal of interest (the received data signals), so that the receiver system 10 locks on to the desired signal. In implementing the canceller 20 and algorithm 30, the received signal is oversampled either in time (FIG. 2) or in space (FIG. 1). The use of an antenna array (receive antennas 11, 11a, FIG. 1) with sufficient spacing effectively oversamples a signal, even if each antenna 11, 11a is critically sampled in time. This signal contains a statistically white component (the signal of interest) and a correlated component (the narrow-band interferer or interfering signal).

The prediction-error filter 16 is computed using correlation statistics of the oversampled signal. Filtering the signal with the prediction-error filter 16 produces an output that is statistically white containing most of the signal of interest, and a small portion of the interference.

The output of the prediction-error filter 16 contains a sufficient facsimile of the desired signal which allows the adaptive decision-feedback equalizer 22 to lock on to the desired signal of interest by making correct decisions on the output data stream. Without the initial filtering provided by the prediction-error filter 16, the adaptive decision-feedback equalizer 22 would not be able to acquire lock.

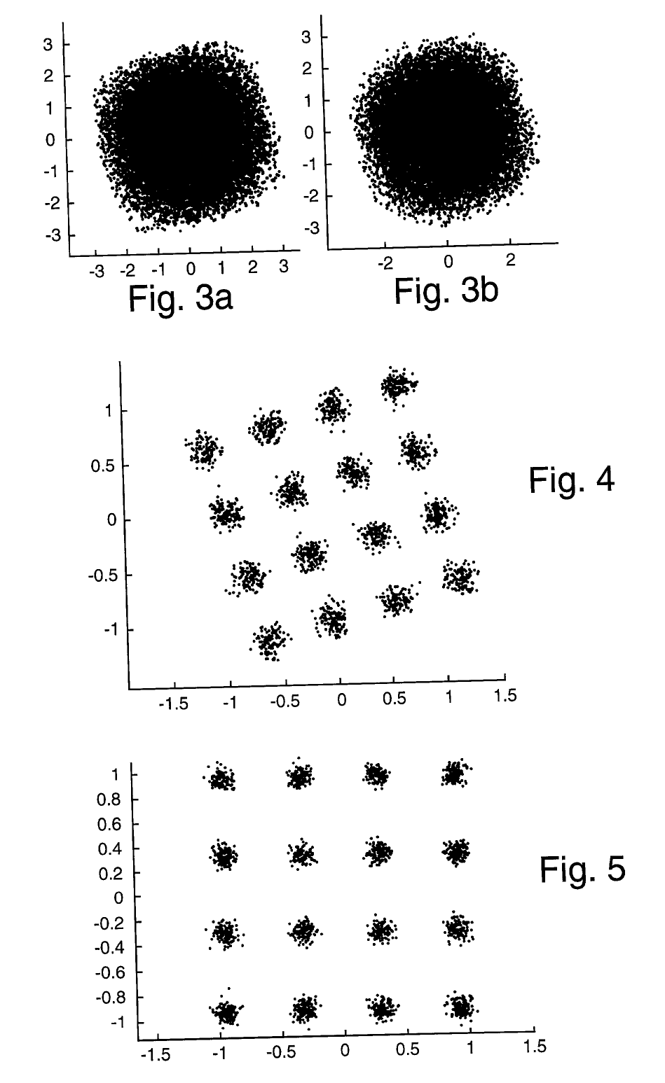

FIG. 3 illustrates input samples at the two antennas 11, 11a of the system 10. FIG. 4 illustrates the output of the prediction error filter 16 of the canceller 20. FIG. 5 illustrates the equalized output of the adaptive decision-feedback equalizer 22 of the canceller 20.

Simulation of the system 10 verifies performance. A two-antenna system 10, such as is shown in FIG. 1, with a desired wideband 16QAM signal, and a narrow-band 8PSK interferer of equal power was simulated to evaluate interference cancellation. FIG. 3 shows the input samples of the inputs at the two antennas 11, 11a, with both signals superimposed on each other. FIG. 4 shows the output of an 11-tap prediction-error filter 16. This signal is the “prediction error”, i.e., everything remaining after predicting the highly-correlated narrowband interferer, which is substantially the 16QAM signal of interest. FIG. 5 shows the output of the adaptive decision-feedback equalizer 22 after a blind adaptation to the output of the prediction-error filter 16. In looking at FIG. 5, it is seen that the signal has been equalized, and the interferer has been removed.

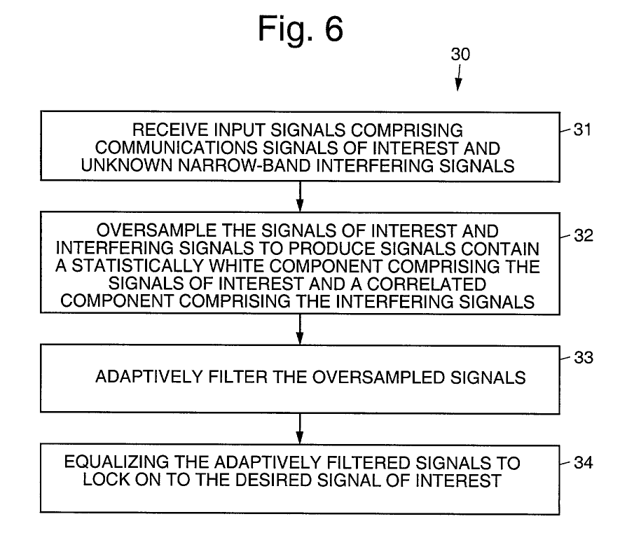

FIG. 6 is a flow chart that illustrates an exemplary interference cancellation method 30 in accordance with the principles of the present invention. The interference cancellation method 30 comprises the following steps.

Input signals comprising communications signals of interest and unknown narrow-band interfering signals are received 31. The received signals are oversampled 32 (either spatially or temporally). The oversampled signals contain a statistically white component comprising the signal of interest and a correlated component comprising the interfering signal.

The oversampled signals are filtered 33 using an adaptively formed prediction-error filter 16 computed using correlation statistics of the oversampled signal to produce an output that is statistically white containing most of the signal of interest, and a small portion of the interference. The filtered signals are equalized 34 by an adaptive decision-feedback equalizer 22 to lock on to the desired signal of interest.

Thus, improved interference cancellers, methods and prediction error algorithms for providing blind narrow-band interference cancellation have been disclosed. It is to be understood that the above-described embodiment is merely illustrative of some of the many specific embodiments that represent applications of the principles of the present invention. Clearly, numerous and other arrangements can be readily devised by those skilled in the art without departing from the scope of the invention.

What is claimed is:

1. Communication apparatus comprising:
a receive antenna for receiving communications signals of interest and unknown narrow-band interfering signals;
a downconverter coupled to the receive antenna;
a signal clock recovery circuit coupled to an output of downconverter;
a sampling circuit coupled to an output of the downconverter and to an output of the signal clock recovery circuit for providing an oversampled signal containing the communications signals of interest and unknown narrow-band interfering signals;
a blind narrow-band interference canceller coupled to an output of the sampling circuit for filtering the communications signals of interest and unknown narrow-band interfering signals to produce an output that is statistically white containing most of the signal of interest, and a small portion of the interference, and for locking on to the desired signal of interest; and
a symbol decoding circuit coupled to an output of the interference canceller for outputting the communications signals of interest without interference.

2. The apparatus recited in claim 1 wherein the blind narrow-band interference canceller comprises:
a prediction-error filter;
a filter adaptation circuit coupled to an output of the prediction-error filter and to the sampling circuit for adapting the filter;
a mixer having a first input coupled to an output of the prediction-error filter;
a carrier tracking loop having an input coupled to an output of the mixer and having an output coupled to a second input of the mixer; and
an adaptive decision-feedback equalizer coupled to an output of the mixer.

3. The apparatus recited in claim 1 further comprising:
a second receive antenna for receiving the communications signals of interest and the unknown narrow-band interfering signals;
a second downconverter coupled to the second receive antenna; and
a multiplexer having inputs coupled to the downconverters and having an output coupled to the blind narrow-band interference canceller.

4. A communication method comprising the steps of:
receiving input signals comprising communications signals of interest and unknown narrow-band interfering signals;
oversampling the signals of interest and interfering signals to produce signals contain a statistically white component comprising the signals of interest and a correlated component comprising the interfering signals;
adaptively filtering the oversampled signals
equalizing the adaptively filtered signals to lock on to the desired signal of interest.

5. The method recited in claim 4 wherein the oversampling step comprises spatially oversampling the signals of interest and interfering signals.

6. The method recited in claim 4 wherein the oversampling step comprises temporally oversampling the signals of interest and interfering signals.

7. The method recited in claim 4 wherein the adaptive filtering step comprises adaptively filtering the oversampled signals using an adaptively formed prediction-error filter that is computed using correlation statistics of the oversampled signal to produce an output that is statistically white containing most of the signal of interest, and a small portion of the interference.

8. The method recited in claim 4 wherein the equalizing step comprises equalizing the adaptively filtered signals an adaptive decision-feedback equalizer to lock on to the desired signal of interest.
